(19) United States
(12) Patent Application Publication
(10) Pub. No.: US 2026/0082651 A1
(43) Pub. Date: Mar. 19, 2026

(54) SEMICONDUCTOR STORAGE DEVICE

(71) Applicant: Kioxia Corporation, Tokyo (JP)

(72) Inventors: Bairu Yan, Yokohama (JP); Toshiya Murakami, Tokyo (JP)

(73) Assignee: Kioxia Corporation, Tokyo (JP)

(21) Appl. No.: 19/079,841

(22) Filed: Mar. 14, 2025

(30) Foreign Application Priority Data
Sep. 19, 2024 (JP) 2024-162673

(51) Int. Cl. H10D 62/80; H10B 12/00; H10D 1/68

(52) U.S. Cl. CPC H10D 62/881; H10B 12/315; H10B 12/482; H10B 12/488; H10D 1/716

(57) ABSTRACT

A semiconductor storage device includes a plurality of memory cells aligned in first and second directions, each memory cell extends in a third direction and includes a MOS transistor and a capacitor, the MOS transistor includes a first insulating layer that extends in the third direction, a semiconductor layer that extends in the third direction to surround a side surface of the first insulating layer and is formed of a two-dimensional material, and a gate electrode that is provided outside the semiconductor layer, the capacitor includes a first electrode, a second electrode, and a capacitor material layer extending in the third direction, the first electrode surrounds a side surface of the second electrode, the capacitor material layer is provided between the first electrode and the second electrode, and the first electrode is in contact with a first end portion of the semiconductor layer in the third direction.

### CROSS-REFERENCE TO RELATED APPLICATIONS

This application is based upon and claims the benefit of priority from Japanese Patent Application No. 2024-162673, filed Sep. 19, 2024, the entire contents of which are incorporated herein by reference.

### FIELD

Embodiments described herein relate generally to a semiconductor storage device.

### BACKGROUND

A semiconductor storage device in which a plurality of memory cells each including a transistor and a capacitor on a semiconductor substrate are three-dimensionally integrated has been proposed.

### BRIEF DESCRIPTION OF THE DRAWINGS

FIG. 1 an electrical circuit diagram illustrating a basic configuration of a semiconductor storage device according to a first embodiment.

FIG. 2 is a perspective view schematically illustrating an example of the basic configuration of the semiconductor storage device according to the first embodiment.

FIG. 3 is a perspective view schematically illustrating another example of the basic configuration of the semiconductor storage device according to the first embodiment.

FIG. 4 is a sectional view schematically illustrating the configuration of the semiconductor storage device according to the first embodiment.

FIG. 5A is a sectional view schematically illustrating a configuration of a MOS transistor in the semiconductor storage device according to the first embodiment.

FIG. 5B is a sectional view schematically illustrating a configuration of a capacitor in the semiconductor storage device according to the first embodiment.

FIG. 6 is a sectional view schematically illustrating a specific structure of the capacitor in the semiconductor storage device according to the first embodiment.

FIG. 7A is a sectional view schematically illustrating a part of a method of manufacturing the semiconductor storage device according to the first embodiment.

FIG. 7B is a sectional view schematically illustrating a part of the method of manufacturing the semiconductor storage device according to the first embodiment.

FIG. 7C is a sectional view schematically illustrating a part of the method of manufacturing the semiconductor storage device according to the first embodiment.

FIG. 7D is a sectional view schematically illustrating a part of the method of manufacturing the semiconductor storage device according to the first embodiment.

FIG. 7E is a sectional view schematically illustrating a part of the method of manufacturing the semiconductor storage device according to the first embodiment.

FIG. 7F is a sectional view schematically illustrating a part of the method of manufacturing the semiconductor storage device according to the first embodiment.

FIG. 7G is a sectional view schematically illustrating a part of the method of manufacturing the semiconductor storage device according to the first embodiment.

FIG. 8 is a sectional view schematically illustrating a configuration of a semiconductor storage device according to a modification of the first embodiment.

FIG. 9 is a sectional view schematically illustrating a configuration of a semiconductor storage device according to a second embodiment.

FIG. 10A is a sectional view schematically illustrating a configuration of a MOS transistor in the semiconductor storage device according to the second embodiment.

FIG. 10B is a sectional view schematically illustrating a configuration of a capacitor in the semiconductor storage device according to the second embodiment.

FIG. 11A is a sectional view schematically illustrating a part of a first method of manufacturing the semiconductor storage device according to the second embodiment.

FIG. 11B is a sectional view schematically illustrating a part of the first method of manufacturing the semiconductor storage device according to the second embodiment.

FIG. 11C is a sectional view schematically illustrating a part of the first method of manufacturing the semiconductor storage device according to the second embodiment.

FIG. 11D is a sectional view schematically illustrating a part of the first method of manufacturing the semiconductor storage device according to the second embodiment.

FIG. 12A is a sectional view schematically illustrating a part of a second method of manufacturing the semiconductor storage device according to the second embodiment.

FIG. 12B is a sectional view schematically illustrating a part of the second method of manufacturing the semiconductor storage device according to the second embodiment.

FIG. 12C is a sectional view schematically illustrating a part of the second method of manufacturing the semiconductor storage device according to the second embodiment.

FIG. 12D is a sectional view schematically illustrating a part of the second method of manufacturing the semiconductor storage device according to the second embodiment.

FIG. 12E is a sectional view schematically illustrating a part of the second method of manufacturing the semiconductor storage device according to the second embodiment.

FIG. 12F is a sectional view schematically illustrating a part of the second method of manufacturing the semiconductor storage device according to the second embodiment.

FIG. 12G is a sectional view schematically illustrating a part of the second method of manufacturing the semiconductor storage device according to the second embodiment.

FIG. 12H is a sectional view schematically illustrating a part of the second method of manufacturing the semiconductor storage device according to the second embodiment.

FIG. 12I is a sectional view schematically illustrating a part of the second method of manufacturing the semiconductor storage device according to the second embodiment.

FIG. 12J is a sectional view schematically illustrating a part of the second method of manufacturing the semiconductor storage device according to the second embodiment.

FIG. 13 is a sectional view schematically illustrating a configuration of a semiconductor storage device according to a modification of the second embodiment.

FIG. 14 is a sectional view schematically illustrating a configuration of a semiconductor storage device according to a third embodiment.

FIG. 15A is a sectional view schematically illustrating a part of a method of manufacturing the semiconductor storage device according to the third embodiment.

FIG. 15B is a sectional view schematically illustrating a part of the method of manufacturing the semiconductor storage device according to the third embodiment.

FIG. 15C is a sectional view schematically illustrating a part of the method of manufacturing the semiconductor storage device according to the third embodiment.

FIG. 15D is a sectional view schematically illustrating a part of the method of manufacturing the semiconductor storage device according to the third embodiment.

FIG. 15E is a sectional view schematically illustrating a part of the method of manufacturing the semiconductor storage device according to the third embodiment.

### DETAILED DESCRIPTION

An aspect of one embodiment is to provide a semiconductor storage device capable of obtaining satisfactory connection between a transistor and a capacitor.

In general, according to one embodiment, a semiconductor storage device includes: a plurality of memory cells that are aligned in a first direction and a second direction intersecting the first direction; each of the plurality of memory cells extends in a third direction intersecting the first and second directions and includes a MOS transistor and a capacitor that is adjacent to the MOS transistor in the third direction, the MOS transistor includes a first insulating layer that extends in the third direction, a semiconductor layer that extends in the third direction to surround a side surface of the first insulating layer and includes a two-dimensional material, and a gate electrode that is provided outside the semiconductor layer, the capacitor includes a first electrode, a second electrode, and a capacitor material layer that extend in the third direction and has a structure in which the first electrode surrounds a side surface of the second electrode and the capacitor material layer is provided between the first electrode and the second electrode, and the first electrode is in contact with a first end portion of the semiconductor layer in the third direction.

Hereinafter, embodiments will be described with reference to the drawings.

### First Embodiment

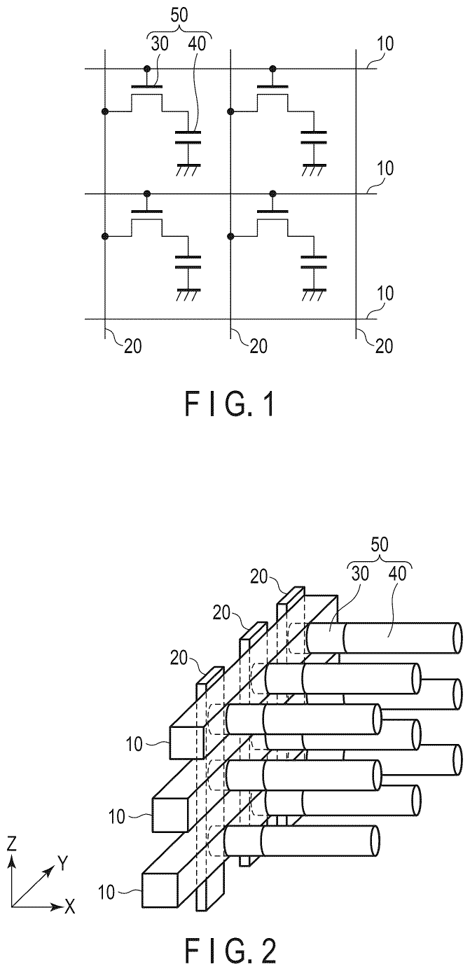

FIG. 1 is an electrical circuit diagram illustrating a basic configuration of a semiconductor storage device according to a first embodiment.

As illustrated in FIG. 1, the semiconductor storage device in the present embodiment is a DRAM and includes a plurality of word lines 10, a plurality of bit lines 20, and a plurality of memory cells 50. As in an ordinary DRAM, each memory cell 50 includes a MOS transistor 30 and a capacitor 40, a gate electrode of the MOS transistor 30 is connected to the word line 10, one of a source terminal and a drain terminal of the MOS transistor 30 is connected to the bit line 20, and the other one of the source terminal and the drain terminal is connected to the capacitor 40.

FIG. 2 is a perspective view schematically illustrating an example of a basic configuration of the semiconductor storage device according to the present embodiment.

As illustrated in FIG. 2, the semiconductor storage device in the present embodiment includes the plurality of word lines 10 that have a three-dimensional structure and each extend in a Y direction (first direction), the plurality of bit lines 20 that each extend in a Z direction (second direction), and the plurality of memory cells 50 that are aligned in the Y direction and the Z direction. Each word line 10 is connected to the plurality of memory cells 50 aligned in the Y direction, and each bit line 20 is connected to the plurality of memory cells 50 aligned in the Z direction. Each memory cell 50 extends in an X direction and includes the MOS transistor 30 and the capacitor 40 that are adjacent to each other in the X direction.

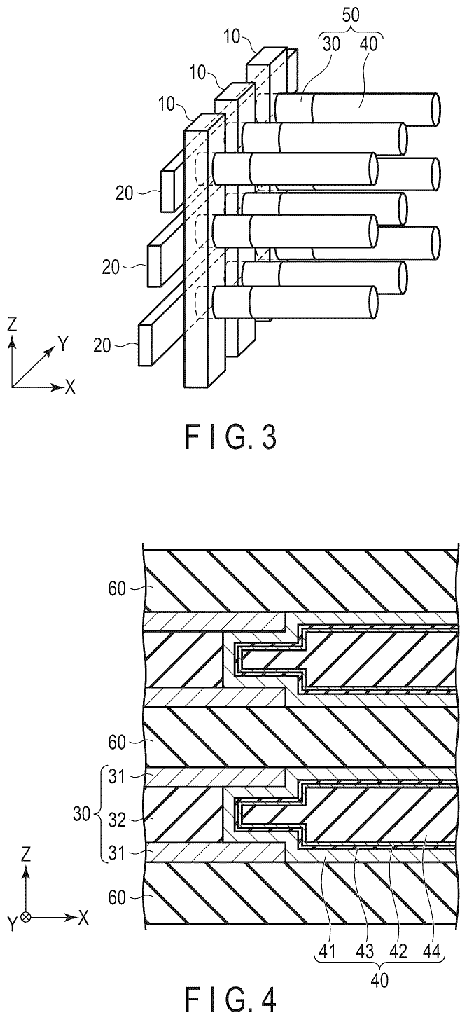

FIG. 3 is a perspective view schematically illustrating another example of the basic configuration of the semiconductor storage device according to the present embodiment.

The basic configuration of the semiconductor storage device illustrated in FIG. 3 is similar to the configuration of the semiconductor storage device illustrated in FIG. 2. However, each of the plurality of word lines 10 extends in the Z direction (first direction), and each of the plurality of bit lines 20 extends in the Y direction (second direction) in FIG. 3. The other basic configuration is similar to the configuration in FIG. 2.

FIG. 4 is a sectional view perpendicular to the Y direction, which schematically illustrates the configuration of the semiconductor storage device according to the present embodiment. Note that although the word lines 10 and the bit lines 20 are not illustrated in FIG. 4 for convenience of explanation, the word lines 10 and the bit lines 20 are provided on the left side of the structure illustrated in FIG. 4 in practice. The same applies to the other drawings, which will be described later.

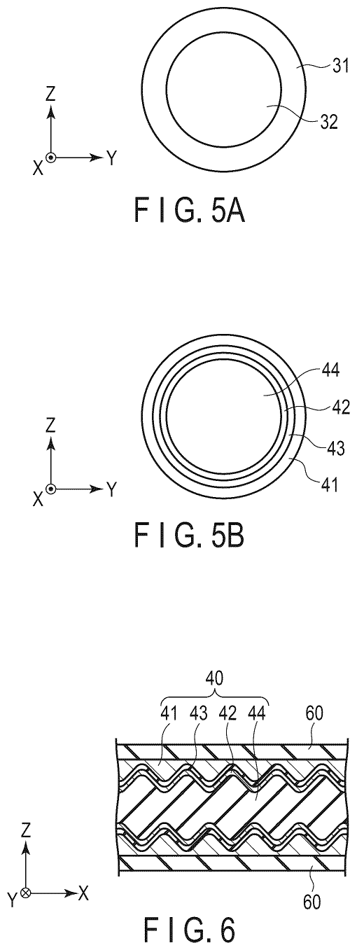

FIG. 5A is a sectional view schematically illustrating a configuration of the MOS transistor 30 in the semiconductor storage device according to the present embodiment in a section perpendicular to the X direction. FIG. 5B is a sectional view schematically illustrating a configuration of the capacitor 40 in the semiconductor storage device according to the present embodiment in a section perpendicular to the X direction.

Note that although the shape of the memory cell 50 including the MOS transistor 30 and the capacitor 40 is a columnar shape in FIGS. 2, 3, 5A, and 5B, the actual shape of the memory cell is close to a prism shape. Note that the shape is not limited to that illustrated in these drawings.

Hereinafter, the configuration of the semiconductor storage device according to the present embodiment will be described with reference to FIGS. 2 (or 3), 4, 5A, and 5B.

As already described, each memory cell 50 in the semiconductor storage device in the present embodiment includes the MOS transistor 30 and the capacitor 40 that extend in the X direction and are adjacent to each other in the X direction. Also, the plurality of memory cells 50 are surrounded by an insulating region 60, and the memory cells that are adjacent to each other are insulated by the insulating region 60.

The MOS transistor 30 includes an insulating layer 32 that extends in the X direction, a semiconductor layer 31 that extends in the X direction to surround a side surface of the insulating layer 32 and is formed of a two-dimensional material, and a gate electrode that is provided outside the semiconductor layer 31. Specifically, the MOS transistor 30 is configured as follows.

The MOS transistor 30 includes the semiconductor layer 31 that has a tubular structure extending in the X direction, and a channel is formed in the semiconductor layer 31. The insulating layer 32 is provided inside an inner side surface of the tubular semiconductor layer 31, and the inside of the semiconductor layer 31 is filled with the insulating layer 32.

The gate electrode of the MOS transistor 30 is included in the word line 10, and a part of the word line 10 functions as the gate electrode of the MOS transistor 30. Specifically, the tubular semiconductor layer 31 penetrates through the gate electrode and extends in the X direction. A gate insulating layer, which is not illustrated, is provided between the semiconductor layer 31 and the gate electrode.

One end portion (first end portion) of the semiconductor layer 31 in the X direction and a region in the vicinity of the first end portion correspond to a region (first terminal region) including one of the source terminal and the drain terminal, and the other end portion (second end portion) of the semiconductor layer 31 in the X direction and a region in the vicinity of the second end portion correspond to a region (second terminal region) including the other one of the source terminal and the drain terminal. The capacitor 40 is connected to the first terminal region of the semiconductor layer 31, and the bit line 20 is connected to the second terminal region of the semiconductor layer 31.

The semiconductor layer 31 is formed of a two-dimensional material. The two-dimensional material has a layered structure formed of one or more monoatomic layers, and atoms constituting the monoatomic layer are strongly bonded through covalent bond inside each monoatomic layer. Also, in a case where the layered structure is formed of two or more monoatomic layers, the layered structure has a structure in which two or more monoatomic layers are stacked, and a van del Waals (vdW) gap is provided between the monoatomic layers that are adjacent in the stacking direction. In the present embodiment, the extending direction of the semiconductor layer 31 (X direction) and the extending direction of the layered structure of the two-dimensional material (the extending direction of the monoatomic layers) are the same direction.

The aforementioned two-dimensional material is preferably selected from a material containing tungsten (W) and sulfur (S) (specifically, WS₂), a material containing tungsten (W) and selenium (Se) (specifically, WSe₂), a material containing molybdenum (Mo) and sulfur (S) (specifically, MoS₂), a material containing molybdenum (Mo) and selenium (Se) (specifically, MoSe₂), and a material containing molybdenum (Mo) and tellurium (Te) (specifically, MoTe₂).

The capacitor 40 includes a first electrode 41, a second electrode 42, a capacitor material layer 43, and an insulating layer 44 each extending in the X direction and has a structure in which the first electrode 41 surrounds a side surface of the second electrode 42, the capacitor material layer 43 is provided between the first electrode 41 and the second electrode 42, and the second electrode 42 is provided outside the insulating layer 44 to surround an outer peripheral surface thereof. The insulating layer 44 can be omitted. In this case, the second electrode 42 has a columnar structure. Specifically, the capacitor 40 is configured as follows.

The capacitor 40 has a columnar structure extending in the X direction and includes the first electrode 41 that is formed of a conductive material, the second electrode 42 that is formed of a conductive material and is provided inside the first electrode 41, the capacitor material layer (capacitor insulating layer, with dielectric properties) 43 that is formed of an insulating material and is provided between the first electrode 41 and the second electrode 42, and the insulating layer 44 that is provided inside the second electrode 42. All of the first electrode 41, the second electrode 42, the capacitor material layer 43, and the insulating layer 44 extend in the X direction, and the first electrode 41, the second electrode 42, and the capacitor material layer 43 substantially function as the capacitor. The first electrode 41 is connected to the MOS transistor 30, and the second electrode 42 functions as a plate electrode.

Specifically, the first electrode 41 is connected, at a part thereof included in the aforementioned first terminal region, to the semiconductor layer 31. More specifically, the first electrode 41 is in contact with the one end portion (first end portion) of the semiconductor layer 31 in the X direction. Since the semiconductor layer 31 has a tubular structure extending in the X direction, the first end portion of the semiconductor layer 31 has a ring shape in a view from the X direction. Therefore, the first electrode 41 is in contact with such a ring-shaped first end portion of the semiconductor layer 31.

In the present embodiment, an end portion of the insulating layer 32, which is provided inside (radially inside) an inner side surface of the semiconductor layer 31, in the X direction is recessed in the X direction relative to the first end portion of the semiconductor layer 31. Therefore, the first electrode 41 is also in contact with a part of an inner side surface of the semiconductor layer 31 located in the vicinity of the first end portion and is further in contact with an end portion of the insulating layer 32 in the X direction in the present embodiment.

In the present embodiment, the first electrode 41 is formed of a single conductive part (first conductive part). The first conductive part is formed of a material containing carbon or a metal element. The first conductive part may be formed of a single element or may be formed of an alloy containing a plurality of elements.

FIG. 6 is a sectional view schematically illustrating a more specific structure of the capacitor 40. As illustrated in FIG. 6, an inner surface of the first conductive part constituting the first electrode 41 has an irregular shape. Therefore, boundary surfaces of the first conductive part (first electrode 41) and the capacitor material layer 43 have an irregular shape, and boundary surfaces of the capacitor material layer 43 and the second electrode 42 also have an irregular shape. The irregular shape of the inner surface of the first conductive part can be formed by a method as will be described later.

As described above, the semiconductor layer 31 of the MOS transistor 30 is formed of a two-dimensional material, and the first electrode 41 of the capacitor 40 is in contact with the one end portion (first end portion) of the semiconductor layer 31 in the X direction, in the present embodiment. With such a configuration, according to the present embodiment, it is possible to significantly reduce a contact resistance between the semiconductor layer 31 and the first electrode 41 and to obtain satisfactory connection between the MOS transistor 30 and the capacitor 40 as will be described below.

With the two-dimensional material, the contact resistance in a direction perpendicular to the thickness direction of the layered structure is significantly lower than the contact resistance in the thickness direction of the layered structure. In other words, with the two-dimensional material, the contact resistance in a direction parallel to the extending direction of the monoatomic layers included in the layered structure (a direction parallel to surfaces constituting the monoatomic layers) is significantly lower than the contact resistance in a direction perpendicular to the extending direction of the monoatomic layers.

In the present embodiment, the extending direction (X direction) of the semiconductor layer 31 and the extending direction of the layered structure of the two-dimensional material are the same, and the first electrode 41 of the capacitor 40 is in contact with the one end portion (first end portion) of the semiconductor layer 31 in the X direction. Therefore, it is possible to significantly reduce the contact resistance between the first electrode 41 and the semiconductor layer 31.

Also, the inner surface of the first conductive part constituting the first electrode 41 has an irregular shape in the present embodiment. Therefore, the boundary surfaces of the first conductive part and the capacitor material layer 43 have an irregular shape, and the boundary surfaces of the capacitor material layer 43 and the second electrode 42 also have an irregular shape. Therefore, it is possible to increase the substantial area of the capacitor 40 and to increase the capacitance of the capacitor 40.

Moreover, there is a concern that it is not possible to sufficiently obtain a contact area between the first electrode 41 and the first end portion of the semiconductor layer 31 due to the first electrode 41 having the irregular shape. Even in such a case, it is possible to sufficiently lower the contact resistance between the first electrode 41 and the semiconductor layer 31 by a contact resistance (contact resistance per unit area) reducing effect.

Furthermore, since the first electrode 41 is also in contact with a part of the inner side surface of the semiconductor layer 31 located in the vicinity of the first end portion in the present embodiment, it is possible to increase the contact area between the first electrode 41 and the semiconductor layer 31. Therefore, it is possible to further reduce the contact resistance.

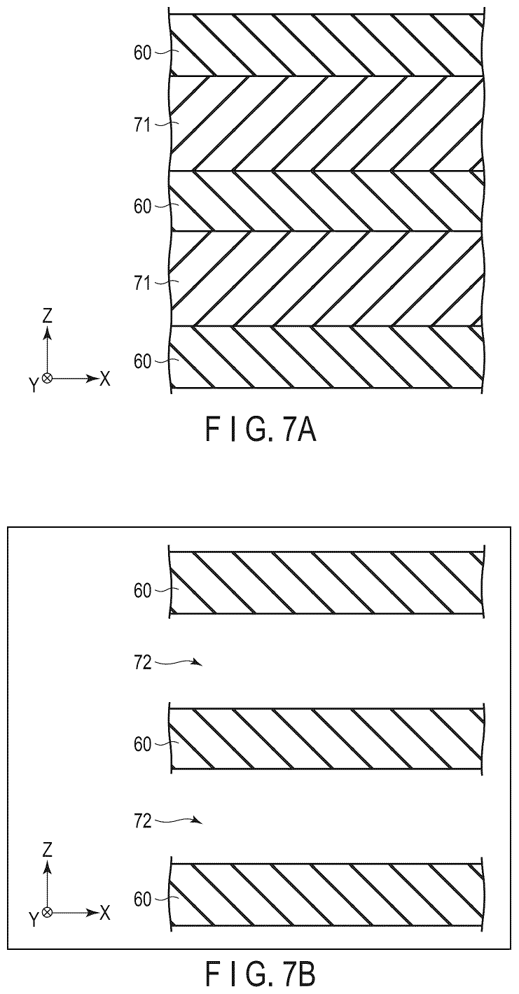

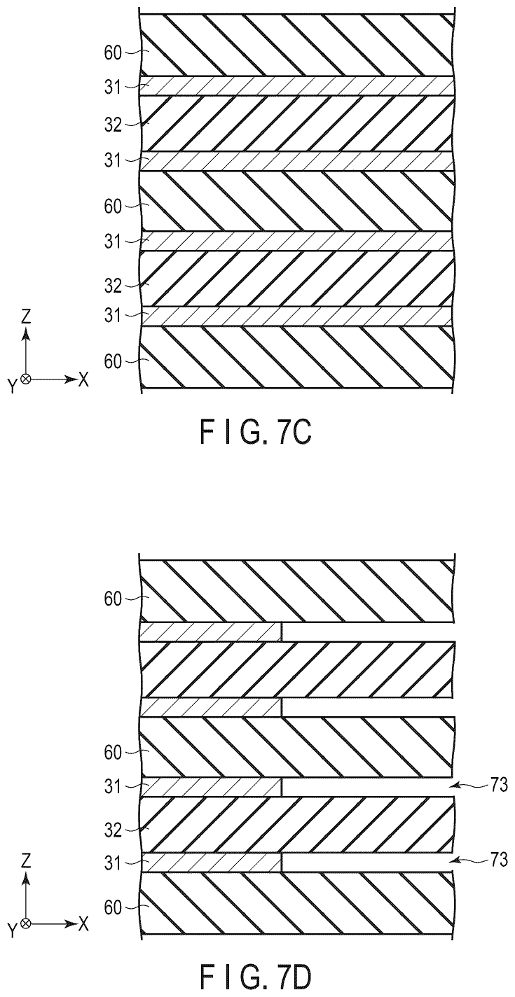

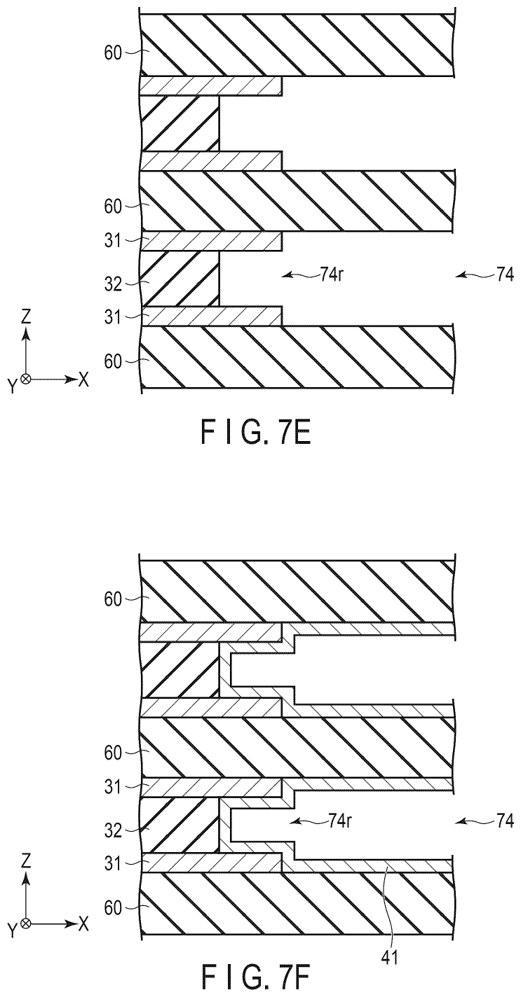

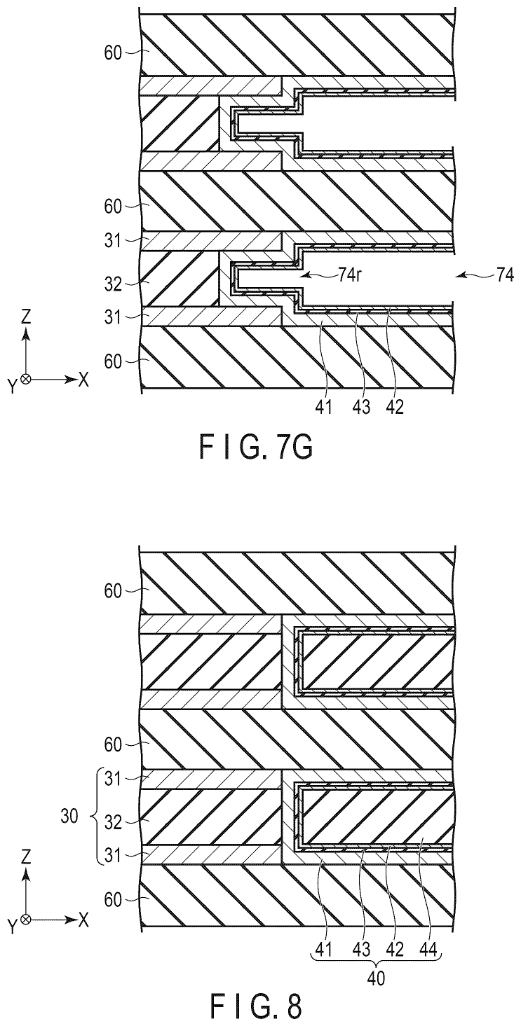

Next, a method of manufacturing the semiconductor storage device according to the present embodiment will be described with reference to the sectional views illustrated in FIGS. 7A to 7G.

First, as illustrated in FIG. 7A, a stacked structure in which insulating layers 60 and sacrificial layers 71 are alternately stacked is formed. For example, silicon oxide is used for the insulating layers 60, and silicon nitride is used for the sacrificial layers 71. Subsequently, the insulating layers 60 and the sacrificial layers 71 are etched to form a plurality of grooves, each of which extends in the X direction and the Z direction and is not illustrated, in the stacked structure. Furthermore, the plurality of grooves are filled with an insulating material (such as a silicon oxide) that is similar to that of the insulating layers 60. The insulating material with which the plurality of grooves are filled separates and insulates memory cells aligned in the Y direction.

Next, the sacrificial layers 71 are selectively etched with the insulating layers 60 left to form spaces 72 as illustrated in FIG. 7B.

Next, semiconductor layers 31 using the two-dimensional material are formed on the inner side surfaces of the insulating layers 60, and insulating layers 32 are further formed inside the semiconductor layers 31, as illustrated in FIG. 7C. For example, silicon nitride or silicon oxynitride is used for the insulating layers 32.

Next, the semiconductor layers 31 are selectively etched with the insulating layers 60 and the insulating layers 32 left to form spaces 73 as illustrated in FIG. 7D.

Next, the insulating layers 32 are selectively etched with the insulating layers 60 and the semiconductor layers 31 left to form spaces 74 as illustrated in FIG. 7E. At this time, the etching is performed such that end portions of the insulating layers 32 are recessed relative to end portions of the semiconductor layers 31 to form recessed portions 74r.

Next, the first electrodes 41 are formed along inner surfaces of the spaces 74 as illustrated in FIG. 7F. As already described, the first electrodes 41 have an irregular shape. Specifically, it is possible to form the irregular shape by methods as will be described below.

The first method is a method of carbonizing an organic structural body. Specifically, it is possible to form a carbon electrode with an irregular shape by evaporating a solvent from a polymer solution under a high humidity condition and further performing carbonization.

The second method is a method of immersing an organic structural body in a conductor dispersion solution. Specifically, it is possible to form a porous ITO electrode by filling gaps of a large number of polymer particles with an ITO dispersion solution by immersing the organic structural body in the ITO dispersion solution and further performing annealing.

The third method is a method of forming porous electrode through dealloying. Specifically, an alloy of two kinds of metal with mutually different solubilities is produced and is then immersed in a corrosive solution to dissolve only one of the metal components. In this manner, the remaining metal component is isolated on the surface and is destabilized. As a result, the remaining metal component is dispersed and aggregated on the surface and to thereby leads to self-organization, and it is thus possible to form a porous metal electrode in the end.

These methods are applied to the spaces 74 and the recessed portions 74r to form the first electrodes 41 with the irregular shapes. Note that a method of forming the first electrodes 41 with the irregular shape is not limited to each of the above methods and it is also possible to use another method.

After the process in FIG. 7F, the capacitor material layers 43 are formed on the first electrodes 41, and the second electrodes 42 are further formed on the capacitor material layers 43, as illustrated in FIG. 7G.

Thereafter, the insulating layers 44 are formed inside the spaces 74 to thereby obtain a structure as illustrated in FIG. 4 and the like.

FIG. 8 is a sectional view perpendicular to the Y direction, which schematically illustrates a configuration of a semiconductor storage device according to a modification of the present embodiment.

In this modification, the end portion of the insulating layer 32, which is provided inside the semiconductor layer 31, in the X direction is not recessed in the X direction relative to the end portion (first end portion) of the semiconductor layer 31 in the X direction, and the end portion of the insulating layer 32 in the X direction and the first end portion of the semiconductor layer 31 are located in the same plane that is substantially perpendicular to the X direction. Therefore, the first electrode 41 is substantially in contact only with the first end portion of the semiconductor layer 31 in this modification. The other basic configuration is similar to the configuration of the aforementioned embodiment.

The configuration in this modification can be formed by performing etching such that the end portion of the insulating layer 32 is located in the same plane as that of the end portion of the semiconductor layer 31 in the process in FIG. 7E in the aforementioned embodiment.

Even in this modification, the basic configuration is similar to the configuration of the aforementioned embodiment, and it is possible to obtain effects similar to the basic effects of the aforementioned embodiment.

### Second Embodiment

Next, a second embodiment will be described. Note that basic matters are similar to those in the first embodiment and description of matters described in the first embodiment will be omitted.

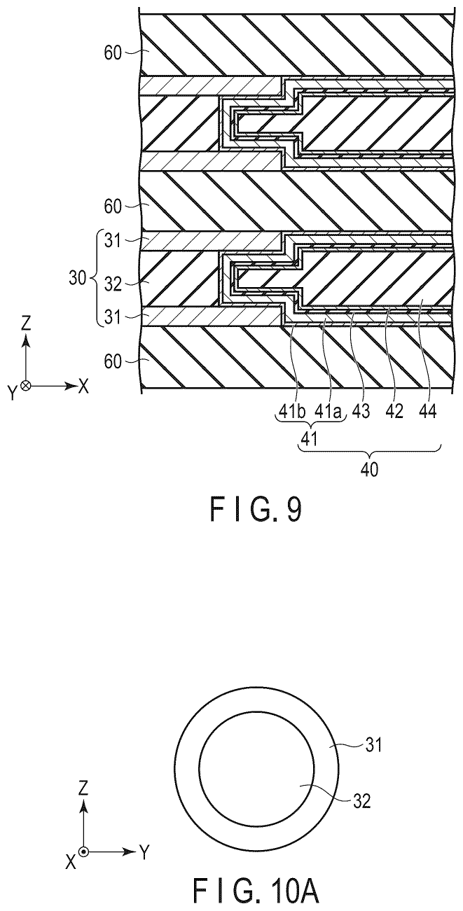

FIG. 9 is a sectional view perpendicular to the Y direction, which schematically illustrates a configuration of a semiconductor storage device according to the present embodiment. Note that although word lines 10 and bit lines 20 are not illustrated in FIG. 9 for convenience of explanation, the word lines 10 and the bit lines 20 are provided on the left side of the structure illustrated in FIG. 9 in practice. The same applies to the other drawings, which will be described later.

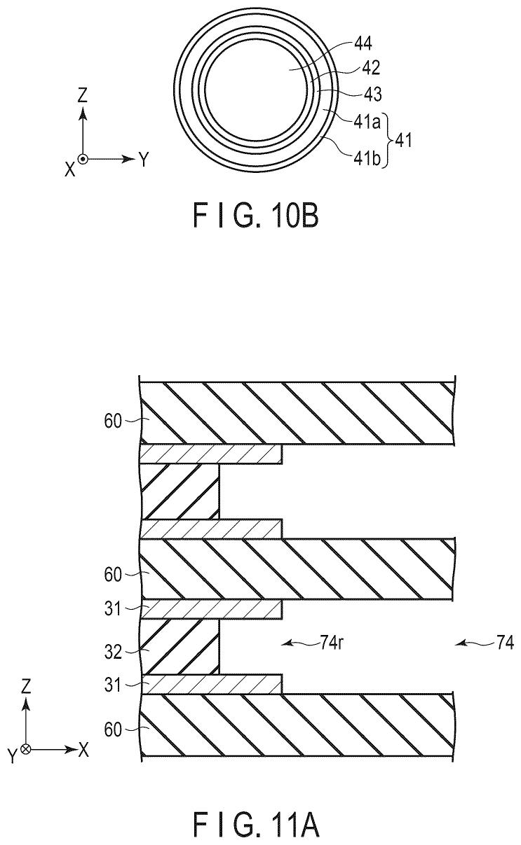

FIG. 10A is a sectional view schematically illustrating a configuration of a MOS transistor 30 in the semiconductor storage device according to the present embodiment in a section perpendicular to the X direction. FIG. 10B is a sectional view schematically illustrating a configuration of a capacitor 40 in the semiconductor storage device according to the present embodiment in a section perpendicular to the X direction.

Note that an overall configuration is similar to that in FIGS. 1, 2, and 3 in the first embodiment. However, although the shape of a memory cell 50 including the MOS transistor 30 and the capacitor 40 is a columnar shape in FIGS. 2, 3, 10A, and 10B, the actual shape of the memory cell 50 is similar to a prism as described above in the first embodiment, in the present embodiment as well. Note that the shape is not limited to that illustrated in these drawings.

Hereinafter, a configuration of the semiconductor storage device according to the present embodiment will be described with reference to FIGS. 2 (or 3), 9, 10A, and 10B.

In the present embodiment, a first electrode 41 of the capacitor 40 includes a first conductive part 41a and a second conductive part 41b. Specifically, the first conductive part 41a is provided between the second conductive part 41b and a capacitor material layer 43.

The first conductive part 41a is basically the first conductive part constituting the first electrode 41 described in the first embodiment. In other words, the first conductive part 41a has a structure similar to that of the first conductive part in the first embodiment and is formed of a material similar to that of the first conductive part in the first embodiment, and an inner surface of the first conductive part 41a has an irregular shape as in FIG. 6 in the first embodiment. Therefore, the boundary surfaces of the first conductive part 41a and the capacitor material layer 43 have an irregular shape, and the boundary surfaces of the capacitor material layer 43 and a second electrode 42 also have an irregular shape, as in the first embodiment.

The second conductive part 41b is provided outside the first conductive part 41a, and both an inner surface (the surface on the side of the first conductive part 41a) and an outer surface (the surface on the side opposite to the inner surface) of the second conductive part 41b have a flat shape.

The first electrode 41 is in contact with one end portion (first end portion) of a semiconductor layer 31 in the X direction in the present embodiment as well, as in the first embodiment. Also, an end portion of an insulating layer 32, which is provided inside the semiconductor layer 31, in the X direction is recessed in the X direction relative to the first end portion of the semiconductor layer 31 in the present embodiment as well, as in the first embodiment. Therefore, the first electrode 41 is also in contact with a part of the inner side surface of the semiconductor layer 31 located in the vicinity of the first end portion and is further in contact with the end portion of the insulating layer 32 in the X direction in the present embodiment as well, as in the first embodiment.

As described above, the basic configuration of the present embodiment is similar to that of the first embodiment, and even in the present embodiment, it is possible to obtain effects similar to those of the first embodiment.

Moreover, although the surface of the first conductive part 41a has an irregular shape in the present embodiment as well, as in the first embodiment, the second conductive part 41b with a flat surface shape is provided outside the first conductive part 41a in the present embodiment. Therefore, the second conductive part 41b with a flat surface shape is in contact with the semiconductor layer 31, and it is possible to sufficiently obtain a contact area between the first electrode 41 and the semiconductor layer 31. Therefore, it is possible to reliably and sufficiently lower the contact resistance between the first electrode 41 and the semiconductor layer 31.

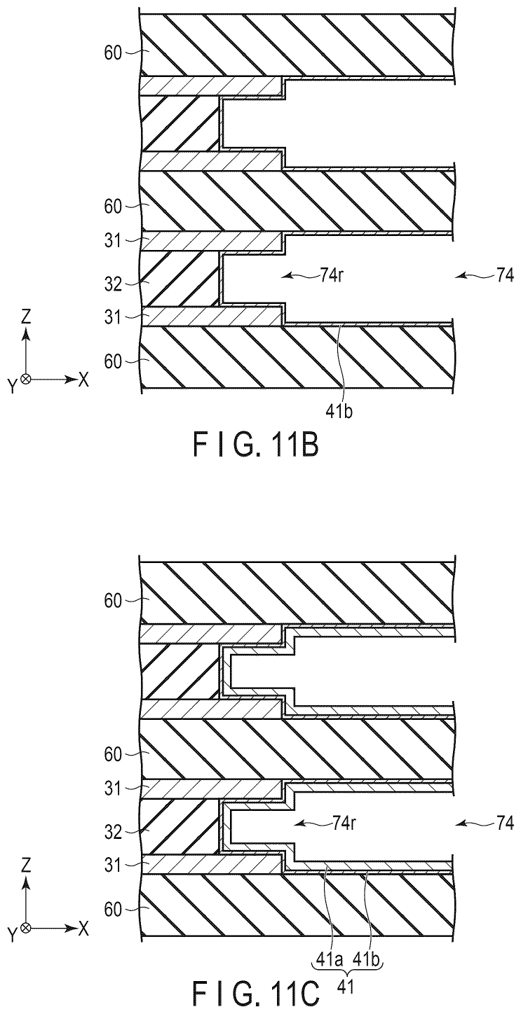

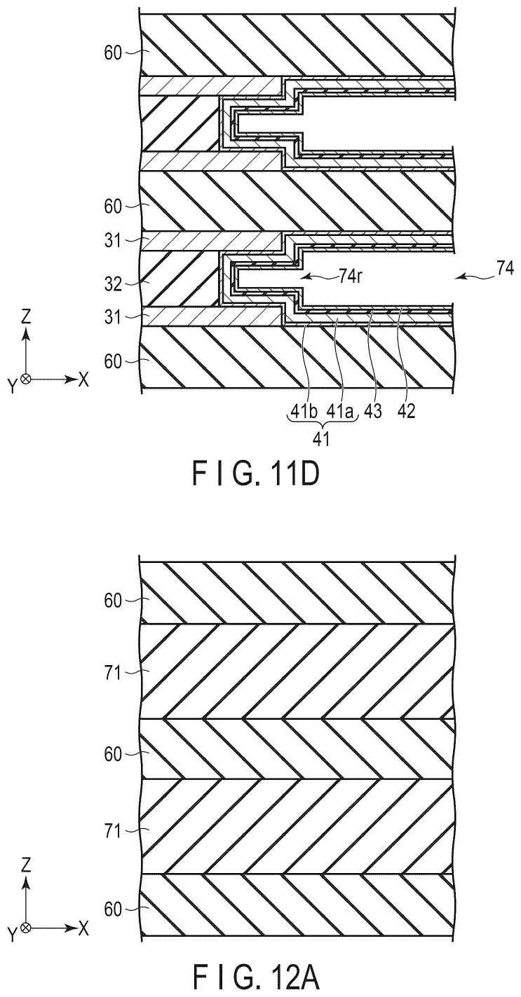

Next, a first method of manufacturing the semiconductor storage device according to the present embodiment will be described with reference to the sectional views illustrated in FIGS. 11A to 11D.

First, a structure as illustrated in FIG. 11A is formed in processes similar to the processes in FIGS. 7A to 7E in the first embodiment.

Next, the second conductive parts 41b are formed along inner surfaces of spaces 74 as illustrated in FIG. 11B.

Next, the first conductive parts 41a are formed along the inner surfaces of the spaces 74 as illustrated in FIG. 11C. As already described, the first conductive parts 41a have an irregular shape. A specific method of forming the first conductive parts 41a is similar to that in the first embodiment. In this manner, the first electrodes 41 including the first conductive parts 41a and the second conductive parts 41b are formed.

Next, the capacitor material layers 43 are formed on the first electrodes 41, and the second electrodes 42 are further formed on the capacitor material layers 43 as illustrated in FIG. 11D.

Thereafter, the insulating layers 44 are formed inside the spaces 74 to thereby obtain a structure as illustrated in FIG. 9 and the like.

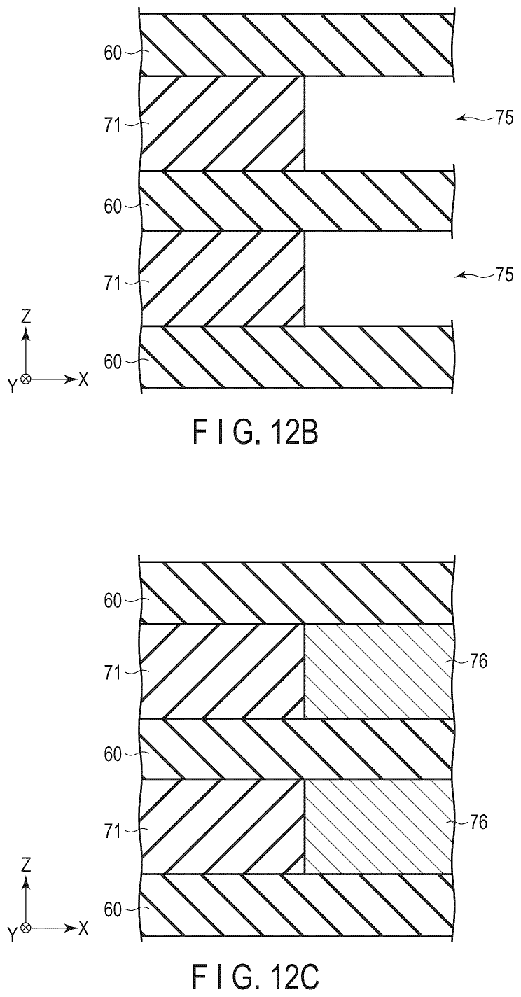

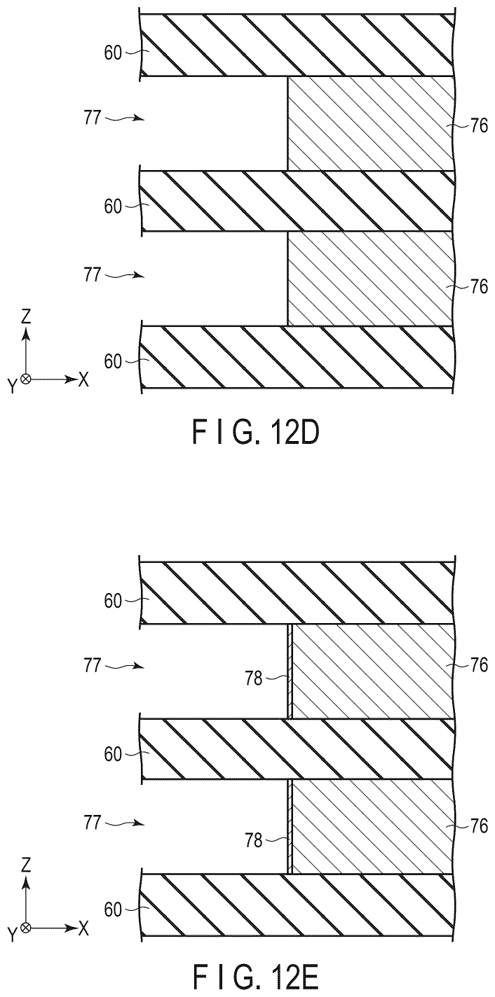

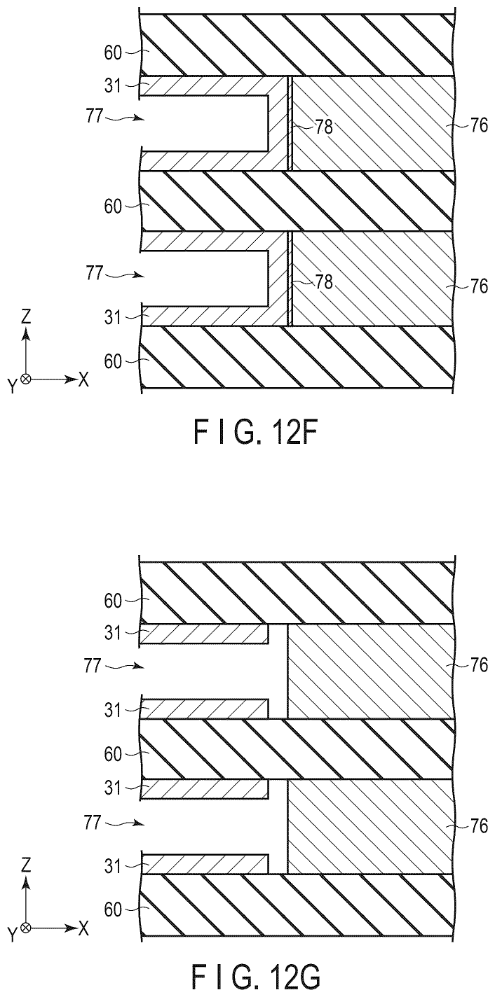

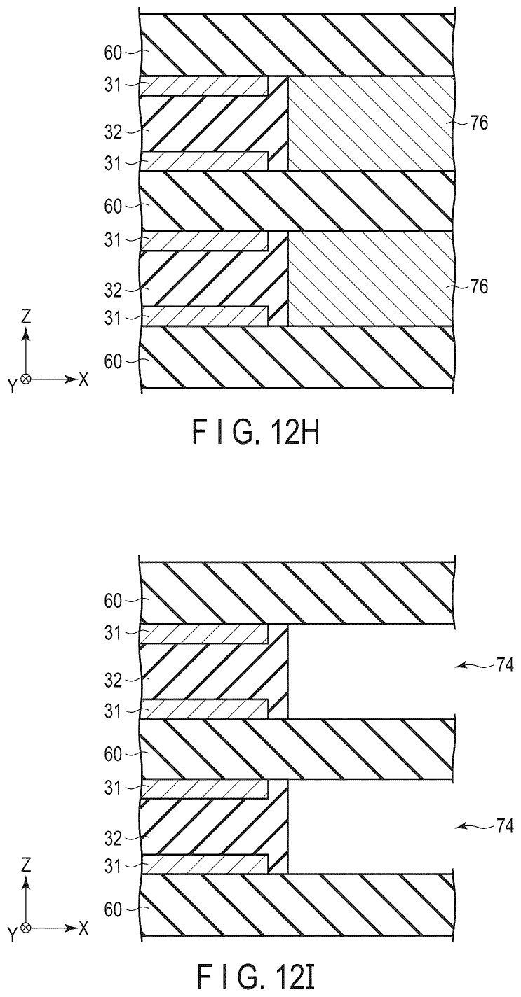

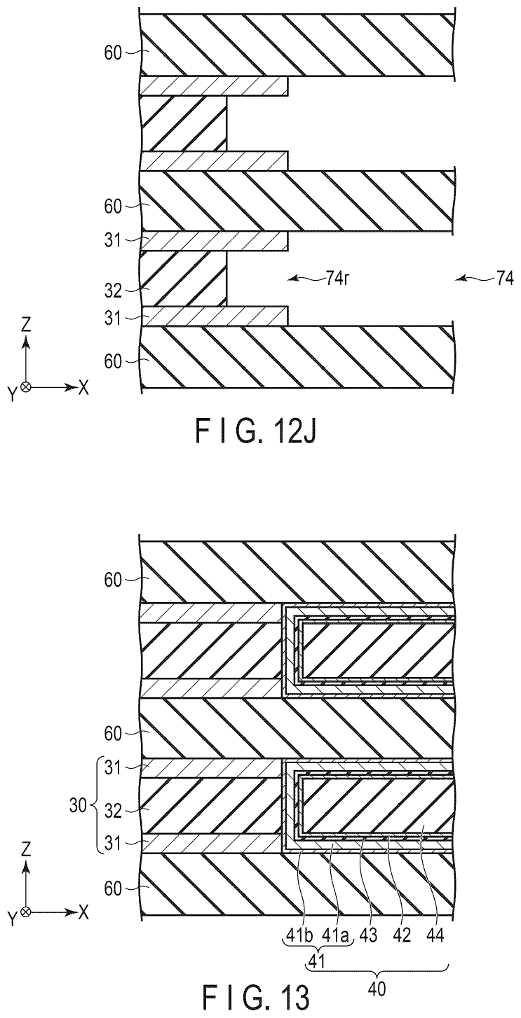

Next, a second method of manufacturing the semiconductor storage device according to the present embodiment will be described with reference to the sectional views illustrated in FIGS. 12A to 12J.

First, a structure as illustrated in FIG. 12A is formed in a process similar to the process in FIG. 7A in the first embodiment.

Next, sacrificial layers 71 are selectively etched with insulating layers 60 left to form spaces 75 as illustrated in FIG. 12B. Next, metal material layers are formed as sacrificial layers 76 inside the spaces 75 as illustrated in FIG. 12C.

Next, the sacrificial layers 71 are selectively etched with the insulating layers 60 and the sacrificial layers 76 left to form spaces 77 as illustrated in FIG. 12D. Next, self-assembled monolayer (SAM) layers 78 are formed on surfaces of the sacrificial layers 76 as illustrated in FIG. 12E.

Next, the semiconductor layers 31 are formed on inner surfaces of the spaces 77 as illustrated in FIG. 12F. Then, a part of the semiconductor layers 31 and the SAM layers 78 are removed to cause surfaces of the sacrificial layers 76 to be exposed as illustrated in FIG. 12G.

Next, the insulating layers 32 are formed inside the spaces 77 as illustrated in FIG. 12H. Then, the sacrificial layers 76 are removed to cause surfaces of the insulating layers 32 to be exposed as illustrated in FIG. 12I. Next, the insulating layers 32 are etched such that the end portions of the insulating layers 32 are recessed relative to the end portions of the semiconductor layers 31 to form recessed portions 74r as illustrated in FIG. 12J.

The following processes are similar to those in the first manufacturing method. In other words, the structure as illustrated in FIG. 9 and the like is obtained by forming the insulating layers 44 inside the spaces 74 in FIG. 11D after the processes similar to those in FIGS. 11B to 11D in the first manufacturing method are performed.

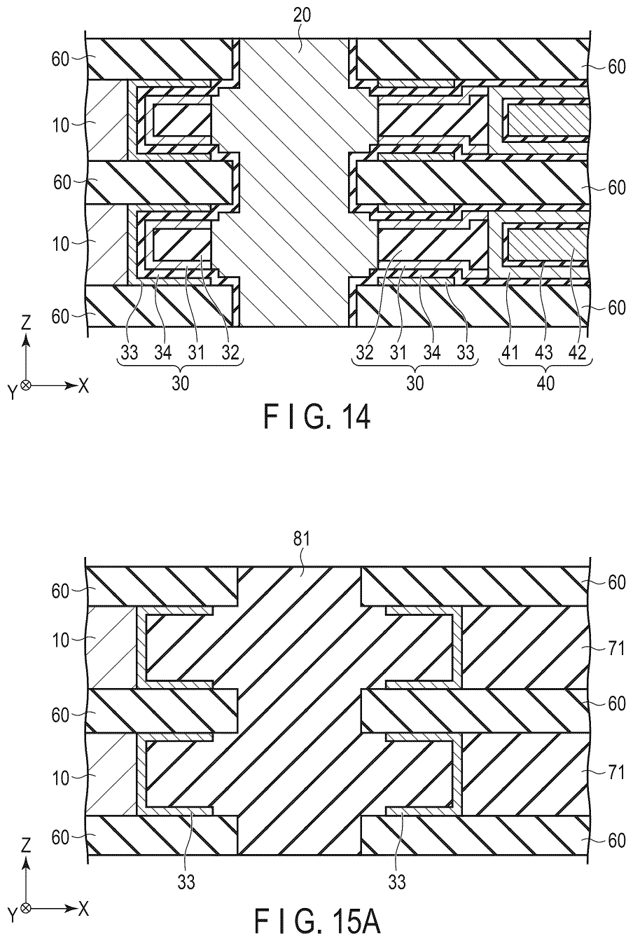

FIG. 13 is a sectional view perpendicular to the Y direction, which schematically illustrates a configuration of a semiconductor storage device according to a modification of the present embodiment.

In this modification, the end portion of the insulating layer 32 in the X direction provided inside the semiconductor layer 31 is not recessed in the X direction relative to the end portion (first end portion) of the semiconductor layer 31 in the X direction, and the end portion of the insulating layer 32 in the X direction and the first end portion of the semiconductor layer 31 are substantially located in the same plane perpendicular to the X direction.

Therefore, the first electrode 41 including the first conductive part 41a and the second conductive part 41b is substantially in contact only with the first end portion of the semiconductor layer 31 in this modification. The other basic configuration is similar to the configuration of the aforementioned embodiment.

The configuration of this modification can be formed by performing etching such that the end portion of the insulating layer 32 is located in the same plane as that of the end portion of the semiconductor layer 31 in the process in FIG. 11A in the aforementioned first manufacturing method. Alternatively, the configuration of this modification can be formed by performing etching such that the end portion of the insulating layer 32 is located in the same plane as that of the end portion of the semiconductor layer 31 in the process in FIG. 12J in the aforementioned second manufacturing method.

The basic configuration is similar to the configuration of the aforementioned embodiment, and it is possible to obtain effects similar to the basic effects of the aforementioned embodiment in this modification as well.

### Third Embodiment

Next, a third embodiment will be described. Note that basic matters are similar to those in the first embodiment and description of matters described in the first embodiment will be omitted.

FIG. 14 is a sectional view perpendicular to the Y direction, which schematically illustrates a configuration of a semiconductor storage device according to the present embodiment.

In the present embodiment, MOS transistors 30 have a structure in which the MOS transistors 30 extend in the X direction and the Y direction, and bit lines 20 extend in the Z direction to penetrate through a region of the plurality of MOS transistors 30 stacked in the Z direction. Specifically, a semiconductor layer 31, an insulating layer 32, a gate electrode 33, and a gate insulating layer 34 of each MOS transistor 30 are provided to surround a side surface of each bit line 20.

The semiconductor layer 31 included in each MOS transistor 30 basically has a tubular shape in a view from the X direction. Also, the semiconductor layer 31 extends in the X direction and the Y direction to surround the side surface of the bit line 20 in a view from the Z direction. As in the first embodiment, the semiconductor layer 31 is formed of a two-dimensional material, and a first end portion of the semiconductor layer 31 is in contact with a first electrode 41 of a capacitor 40. Also, a second end portion of the semiconductor layer 31 is in contact with the bit line 20 to surround the side surface of the bit line 20. The end portion of the insulating layer 32 and the second end portion of the semiconductor layer 31 are substantially located in the same plane along the Z direction. Note that an end portion of the insulating layer 32 on the side of a direction toward the center of the bit line 20 may be recessed in a direction in which the end portion is spaced away from the center of the bit line 20 relative to the end portion (second end portion) of the semiconductor layer 31 on the side of the direction toward the center of the bit line 20. Also, the gate electrode 33 is connected to a word line 10 extending in the Y direction.

The capacitor 40 includes the first electrode 41, a second electrode 42, and a capacitor material layer 43. As in the first embodiment, an inner surface of a first conductive part of the first electrode 41 has an irregular shape, boundary surfaces of the first conductive part (first electrode 41) and the capacitor material layer 43 have an irregular shape, and boundary surfaces of the capacitor material layer 43 and the second electrode 42 also have an irregular shape.

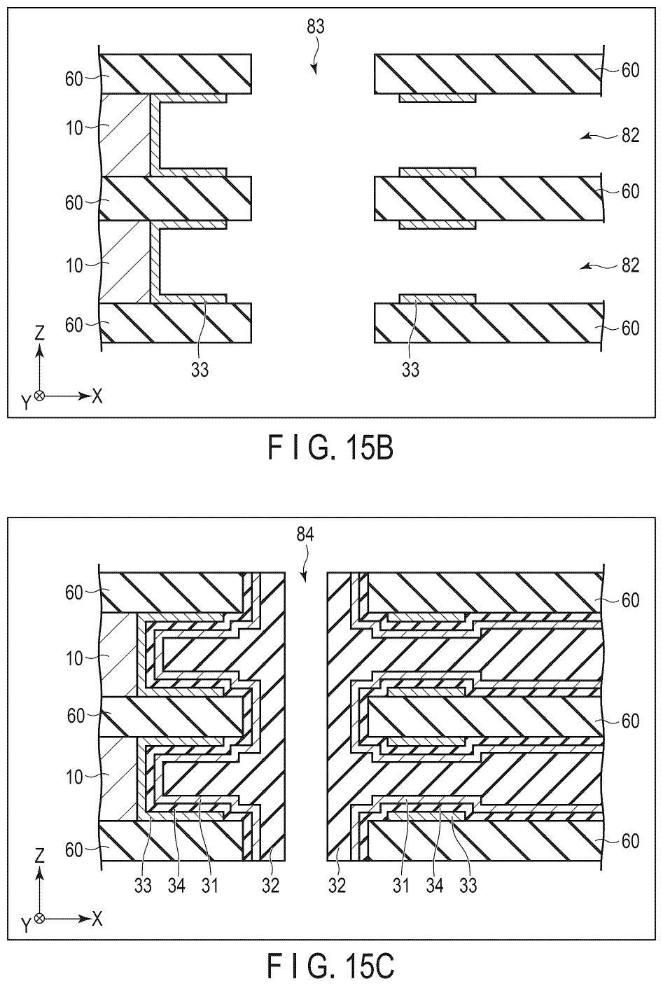

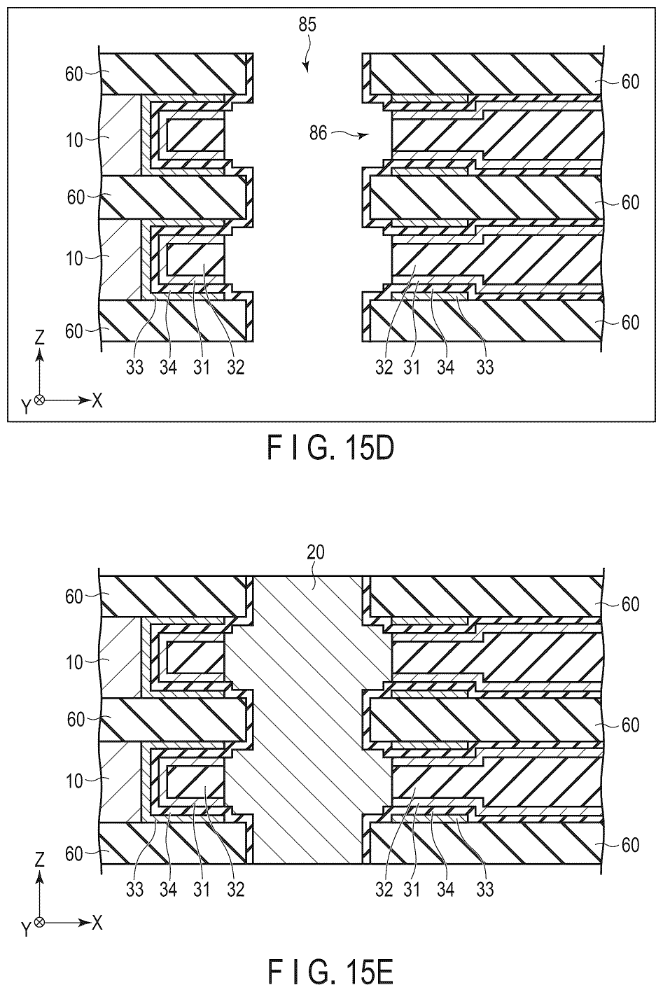

Next, a method of manufacturing the semiconductor storage device according to the present embodiment will be described with reference to the sectional views illustrated in FIGS. 15A to 15E.

As in the process in FIG. 7A in the first embodiment, a stacked structure in which insulating layers 60 and sacrificial layers 71 are alternately stacked in the Z direction is formed first in the present embodiment as well. Subsequently, the insulating layers 60 and the sacrificial layers 71 are etched to form a plurality of grooves, each of which extends in the X direction and the Z direction and is not illustrated, in the stacked structure.

Furthermore, the plurality of grooves are filled with an insulating material (such as silicon oxide) that is similar to that of the insulating layers 60. The insulating material with which the plurality of grooves are filled separates and insulates the memory cells aligned in the Y direction.

Next, a structure as illustrated in FIG. 15A is formed. Specifically, a hole for the bit line 20 is formed first. Subsequently, a part of the sacrificial layers 71 are removed to form spaces for the MOS transistors 30. Thereafter, conductive films that are to serve the gate electrodes 33 and sacrificial layers (both of which are not illustrated) are formed in order on inner side surfaces of the holes for the bit lines 20 with the spaces for the MOS transistors 30 filled. The hole for the bit line 20 is not completely filled with the sacrificial layers. Subsequently, the inner side surface of the hole for the bit line 20 and the conductive films in the vicinity thereof are exposed by etching the sacrificial layers. The gate electrodes 33 are formed along the inner surface of the space by selectively removing the exposed conductive films. Thereafter, the hole for the bit line 20 and the spaces for the MOS transistors 30 are filled with sacrificial layers 81. Furthermore, a part of the sacrificial layers 71 is removed to form spaces for the word lines 10, and the word lines 10 are formed inside the spaces. In this manner, the structure as illustrated in FIG. 15A is obtained.

Next, a part of the sacrificial layers 71 is removed to form spaces 82 for the capacitors 40, and further, the sacrificial layers 81 are removed to form a hole 83 as illustrated in FIG. 15B.

Next, the gate insulating layers 34, the semiconductor layers 31, and the insulating layers 32 are formed inside the spaces 82 and the hole 83 as illustrated in FIG. 15C. At this time, the hole 83 is not completely filled with the insulating layers 32 such that a hole 84 is left.

Next, the semiconductor layers 31 and the insulating layers 32 are etched via the hole 84 to form a hole 85 and recessed portions 86 as illustrated in FIG. 15D. The end portions (second end portions) of the semiconductor layers 31 in the X direction are exposed by forming the recessed portions 86.

Next, the bit line 20 is formed by filling the hole 85 and the recessed portions 86 as illustrated in FIG. 15E.

The following basic processes are similar to those in the first embodiment. In other words, the semiconductor layers 31 and the insulating layers 32 in regions where the MOS transistors 30 are to be formed are left, and the semiconductor layers 31 and the insulating layers 32 in regions where the capacitors 40 are to be formed are removed. In this manner, spaces for the capacitors 40 are formed, and the structure as illustrated in FIG. 14 is obtained by forming the first electrodes 41, the second electrodes 42, and the capacitor material layers 43 inside the spaces for the capacitors 40.

As described above, the basic configuration of the present embodiment is similar to that of the first embodiment, and even in the present embodiment, it is possible to obtain effects similar to those in the first embodiment. It is possible to apply each of the aforementioned embodiments and modifications to the present embodiment as well.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A semiconductor storage device comprising:
a plurality of memory cells that are aligned in a first direction and a second direction intersecting the first direction, wherein
each of the plurality of memory cells extends in a third direction intersecting the first and second directions and includes a MOS transistor and a capacitor that is adjacent to the MOS transistor in the third direction,
the MOS transistor includes a first insulating layer that extends in the third direction, a semiconductor layer that extends in the third direction to surround a side surface of the first insulating layer and includes a two-dimensional material, and a gate electrode that is provided outside the semiconductor layer,
the capacitor includes a first electrode, a second electrode, and a capacitor material layer that extend in the third direction and has a structure in which the first electrode surrounds a side surface of the second electrode and the capacitor material layer is provided between the first electrode and the second electrode, and
the first electrode is in contact with a first end portion of the semiconductor layer in the third direction.

2. The semiconductor storage device of claim 1, wherein the semiconductor layer has a tubular structure that extends in the third direction.

3. The semiconductor storage device of claim 2, wherein the first end portion has a ring shape in a view from the third direction.

4. The semiconductor storage device of claim 1, wherein the first electrode is in contact with a part of an inner side surface of the semiconductor layer that is located in a vicinity of the first end portion.

5. The semiconductor storage device of claim 1, wherein
the first electrode includes a first conductive part, and
respective boundary surfaces of the first conductive part and the capacitor material layer have an irregular shape.

6. The semiconductor storage device of claim 5, wherein the first conductive part is formed of a material containing carbon or a metal element.

7. The semiconductor storage device of claim 5, wherein
the first electrode further includes a second conductive part, and
the first conductive part is provided between the second conductive part and the capacitor material layer.

8. The semiconductor storage device of claim 1, wherein the two-dimensional material is selected from a material containing tungsten (W) and sulfur (S), a material containing tungsten (W) and selenium (Se), a material containing molybdenum (Mo) and sulfur (S), a material containing molybdenum (Mo) and selenium (Se), and a material containing molybdenum (Mo) and tellurium (Te).

9. The semiconductor storage device of claim 1, wherein the first electrode is in contact with an end portion of the first insulating layer in the third direction.

10. The semiconductor storage device of claim 9, wherein the end portion of the first insulating layer in the third direction is recessed in the third direction relative to the first end portion of the semiconductor layer.

11. The semiconductor storage device of claim 9, wherein the end portion of the first insulating layer in the third direction and the first end portion of the semiconductor layer are located in a substantially same plane.

12. The semiconductor storage device of claim 1, wherein
the capacitor further includes a second insulating layer that extends in the third direction, and
the second electrode is provided outside the second insulating layer.

13. The semiconductor storage device of claim 1, further comprising:
an insulating region that insulates memory cells of the plurality of memory cells that are adjacent to each other.

14. The semiconductor storage device of claim 1, further comprising:
a word line that connects the plurality of memory cells aligned in the first direction, wherein
the word line includes the gate electrode.

15. The semiconductor storage device of claim 1, further comprising:
a bit line that connects the plurality of memory cells aligned in the second direction, wherein
the bit line is connected to a region including a second end portion of the semiconductor layer in the third direction.

16. The semiconductor storage device of claim 1, wherein
the first electrode includes a first conductive part, and a second conductive part,
a boundary surface of the first conductive part has an irregular shape and a boundary surface of the second conductive part is flat.

17. The semiconductor storage device of claim 16, wherein the boundary surface of the second conductive part is in contact with the semiconductor layer.

18. The semiconductor storage device of claim 4, wherein the first electrode is in contact with the part of the inner side surface of the semiconductor layer that is closer to the first end portion of the semiconductor layer than a second end of the semiconductor layer that is on an opposite in the third direction.

19. The semiconductor storage device of claim 1, wherein the capacitor has a columnar shape.

20. The semiconductor storage device of claim 1, wherein the capacitor has a prism shape.
